(19) United States
(12) Patent Application Publication
(10) Pub. No.: US 2025/0386681 A1
(43) Pub. Date: Dec. 18, 2025

(54) TRANSISTOR, DISPLAY DEVICE AND ELECTRONIC DEVICE HAVING THE TRANSISTOR, AND MANUFACTURING METHOD THEREOF

(71) Applicant: Samsung Display Co., Ltd., Yongin-Si (KR)

(72) Inventors: Soo Jung CHAE, Yongin-si (KR); Tetsuhiro TANAKA, Yongin-si (KR); Dong Hwan KIM, Yongin-si (KR); Seok Hwan BANG, Yongin-si (KR); June Whan CHOI, Yongin-si (KR)

(21) Appl. No.: 19/056,738

(22) Filed: Feb. 19, 2025

(30) Foreign Application Priority Data
Jun. 17, 2024 (KR) 10-2024-0078254
Oct. 10, 2024 (KR) 10-2024-0137793

(51) Int. Cl. H10K 59/124; H10K 59/12

(52) U.S. Cl. CPC H10K 59/124; H10K 59/1201

(57) ABSTRACT

A transistor may include: a buffer layer disposed on a substrate, an oxide semiconductor layer disposed on the buffer layer and including a first region, a second region, and a channel region disposed between the first region and the second region; a gate insulating layer disposed on the semiconductor layer; a gate electrode disposed on the gate insulating layer, the gate electrode overlapping the channel region; and an interlayer insulating layer disposed over the gate electrode. A concentration of hydrogen (H) in the buffer layer may be 4×10²⁰ atoms/cm³ to 20×10²⁰ atoms/cm³.

### CROSS-REFERENCE TO RELATED APPLICATION

The present application claims priority under 35 U.S.C. § 119(a) to Korean patent application No. 10-2024-0078254 filed on Jun. 17, 2024, and 10-2024-0137793 filed on Oct. 10, 2024, in the Korean Intellectual Property Office, the entire disclosure of which is incorporated herein by reference.

### BACKGROUND

### 1. Technical Field

The present disclosure generally relates to a transistor, a display device and an electronic device having the transistor, and a manufacturing method thereof.

### 2. Related Art

With the development of information technologies, the importance of a display device which is a connection medium between a user and information increases. Accordingly, research and development for improving the reliability of the display device have been continuously conducted.

### SUMMARY

Embodiments provide a transistor having improved reliability, a display device including the transistor, and an electronic device including the display device.

Embodiments also provide a manufacturing method of a transistor having improved reliability.

In accordance with an aspect of the present disclosure, there is provided a transistor including: a buffer layer disposed on a substrate; an oxide semiconductor layer disposed on the buffer layer and including a first region, a second region, and a channel region disposed between the first region and the second region; a gate insulating layer disposed on the semiconductor layer; a gate electrode disposed on the gate insulating layer, the gate electrode overlapping the channel region; and an interlayer insulating layer disposed over the gate electrode, wherein a concentration of hydrogen (H) in the buffer layer is 4×10²⁰ atoms/cm³ to 20×10²⁰ atoms/cm³.

At a temperature of 400° C., a concentration of hydrogen gas (H₂) discharged from the buffer layer may be 1×10¹⁹ atoms/cm³ to 10×10¹⁹ atoms/cm³. At a temperature of 400° C., a concentration of moisture (H₂O) discharged from the buffer layer may be 1×10¹⁹ atoms/cm³ to 20×10¹⁹ atoms/cm³.

At a temperature of 400° C., a concentration of hydrogen gas (H₂) discharged from the buffer layer may be 1×10¹⁹ atoms/cm³ to 5×10¹⁹ atoms/cm³.

At a temperature of 400° C., a concentration of moisture (H₂O) discharged from the buffer layer may be 1×10¹⁹ atoms/cm³ to 10×10¹⁹ atoms/cm³.

A concentration of hydrogen (H) in the gate insulating layer may be 5×10²⁰ atoms/cm³ to 30×10²⁰ atoms/cm³.

At a temperature of 400° C., a concentration of hydrogen gas (H₂) discharged from the gate insulating layer may be 10×10¹⁹ atoms/cm³ to 60×10¹⁹ atoms/cm³.

A concentration of hydrogen (H) in the interlayer insulating layer may be 4×10²⁰ atoms/cm³ to 20×10²⁰ atoms/cm³.

At a temperature of 400° C., a concentration of hydrogen gas (H₂) discharged from the interlayer insulating layer may be 1×10¹⁹ atoms/cm³ to 10×10¹⁹ atoms/cm³.

At a temperature of 400° C., a concentration of hydrogen gas (H₂) discharged from the interlayer insulating layer may be 1×10¹⁹ atoms/cm³ to 7×10¹⁹ atoms/cm³.

A threshold voltage of the transistor may be 0 V to −3.5 V.

A sheet resistance of the interlayer insulating layer may be 1200 Ω/sq or less and the gate electrode may include aluminum.

In accordance with another aspect of the present disclosure, there is provided a method of manufacturing a transistor, the method including: forming a buffer layer; forming a semiconductor layer on the buffer layer, the semiconductor layer including a first region, a second region, and a channel region disposed between the first region and the second region; forming a gate insulating layer on the semiconductor layer; forming a gate electrode on the gate insulating layer, the gate electrode overlapping the channel region; and forming an interlayer insulating layer over the gate electrode, wherein the buffer layer is formed such that a concentration of hydrogen (H) in the buffer layer is 4×10²⁰ atoms/cm³ to 20×10²⁰ atoms/cm³.

The gate insulating layer may be formed such that a concentration of hydrogen (H) in the gate insulating layer is 5×10²⁰ atoms/cm³ to 30×10²⁰ atoms/cm³. The interlayer insulating layer may be formed such that a concentration of hydrogen (H) in the interlayer insulating layer is 4×10²⁰ atoms/cm³ to 20×10²⁰ atoms/cm³.

The buffer layer may be formed such that, at a temperature of 400° C., a concentration of hydrogen gas (H₂) discharged from the buffer layer is 1×10¹⁹ atoms/cm³ to 10×10¹⁹ atoms/cm³, and a concentration of moisture (H₂O) discharged from the buffer layer is 1×10¹⁹ atoms/cm³ to 20×10¹⁹ atoms/cm³. The gate insulating layer may be formed such that, at a temperature of 400° C., a concentration of hydrogen gas (H₂) discharged from the gate insulating layer is 10×10¹⁹ atoms/cm³ to 60×10¹⁹ atoms/cm³. The interlayer insulating layer may be formed such that, at a temperature of 400° C., a concentration of hydrogen gas (H₂) discharged from the interlayer insulating layer is 1×10¹⁹ atoms/cm³ to 10×10¹⁹ atoms/cm³.

The forming of the semiconductor layer may include: forming a base oxide semiconductor layer including an oxide semiconductor; forming a buffer semiconductor layer by patterning the base oxide semiconductor layer; and doping an impurity into both end portions of the buffer semiconductor layer.

In accordance with still another aspect of the present disclosure, there is provided a display device including: a light emitting element; and a transistor electrically connected to the light emitting element, wherein the transistor includes: a buffer layer disposed on a substrate; an oxide semiconductor layer disposed on the buffer layer, the semiconductor layer including a first region, a second region, and a channel region disposed between the first region and the second region; a gate insulating layer disposed on the semiconductor layer; a gate electrode disposed on the gate insulating layer, the gate electrode overlapping the channel region; and an interlayer insulating layer disposed over the gate electrode, wherein a concentration of hydrogen (H) in the buffer layer is 4×10²⁰ atoms/cm³ to 20×10²⁰ atoms/cm³.

A concentration of hydrogen (H) in the gate insulating layer may be 5×10²⁰ atoms/cm³ to 30×10²⁰ atoms/cm³. A concentration of hydrogen (H) in the interlayer insulating layer may be 4×10²⁰ atoms/cm³ to 20×10²⁰ atoms/cm³. At a temperature of 400° C., a concentration of hydrogen gas (H₂) discharged from the buffer layer may be 1×10¹⁹ atoms/cm³ to 10×10¹⁹ atoms/cm³. At a temperature of 400° C., a concentration of moisture (H₂O) discharged from the buffer layer may be 1×10¹⁹ atoms/cm³ to 20×10¹⁹ atoms/cm³. At a temperature of 400° C., a concentration of hydrogen gas (H₂) discharged from the gate insulating layer may be 10×10¹⁹ atoms/cm³ to 60×10¹⁹ atoms/cm³. At a temperature of 400° C., a concentration of hydrogen gas (H₂) discharged from the interlayer insulating layer may be 1×10¹⁹ atoms/cm³ to 10×10¹⁹ atoms/cm³.

A threshold voltage of the transistor may be 0 V to −3.5 V. A sheet resistance of the interlayer insulating layer may be 1200 Ω/sq or less. The gate electrode may include aluminum.

In accordance with an aspect of the present disclosure, there is provided an electronic device including: a processor and a display device. The display device includes: a light emitting element; and a transistor electrically connected to the light emitting element, wherein the transistor includes: a buffer layer disposed on a substrate; a semiconductor layer disposed on the buffer layer, the semiconductor layer including a first region, a second region, and a channel region disposed between the first region and the second region; a gate insulating layer disposed on the semiconductor layer; a gate electrode disposed on the gate insulating layer, the gate electrode overlapping the channel region; and an interlayer insulating layer disposed over the gate electrode, wherein a concentration of hydrogen (H) in the buffer layer is 4×10²⁰ atoms/cm³ to 20×10²⁰ atoms/cm³.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic plan view illustrating a transistor in accordance with an embodiment of the present disclosure.

FIG. 2 is a schematic sectional view taken along line I-I′ shown in FIG. 1.

FIG. 3 is a graph illustrating threshold voltage of the transistor according to concentration of hydrogen gas (H₂) discharged from a buffer layer at a temperature of 400° C.

FIG. 4 is a graph illustrating threshold voltage of the transistor according to concentration of moisture (H₂O) discharged from the buffer layer at a temperature of 400° C.

FIG. 5 is a graph illustrating threshold voltage difference value of the transistor according to concentration of hydrogen gas (H₂) discharged from a gate insulating layer at a temperature of 400° C.

FIGS. 6, 7, 8, 9, 10, 11 and 12 are schematic sectional views illustrating a manufacturing method of a transistor in accordance with an embodiment of the present disclosure.

FIG. 13 is a schematic plan view illustrating a display device in accordance with an embodiment of the present disclosure.

FIG. 14 is a schematic sectional view illustrating a display panel shown in FIG. 13.

FIG. 15 is a schematic circuit diagram illustrating an electrical connection relationship of components included in each of pixels shown in FIG. 13.

FIG. 16 is a schematic sectional view illustrating a pixel in accordance with an embodiment of the present disclosure.

FIG. 17 is a block diagram of an electronic device according to an embodiment.

FIG. 18 shows schematic views of various embodiments of an electronic device.

### DETAILED DESCRIPTION

The present disclosure may apply various changes and different shape, therefore only illustrate in detail with particular examples. However, the examples do not limit to certain shapes but apply to all the change and equivalent material and replacement. The drawings included are illustrated a fashion where the figures are expanded for the better understanding.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the present disclosure. As used herein, the singular forms are intended to include the plural forms as well, unless the context clearly indicates otherwise.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

The present disclosure generally relates to a transistor, a display device and an electronic device having the transistor, and a manufacturing method thereof. Hereinafter, a transistor, a display device and an electronic device having the transistor, and a manufacturing method thereof in accordance with an embodiment of the present disclosure will be described with reference to the accompanying drawings.

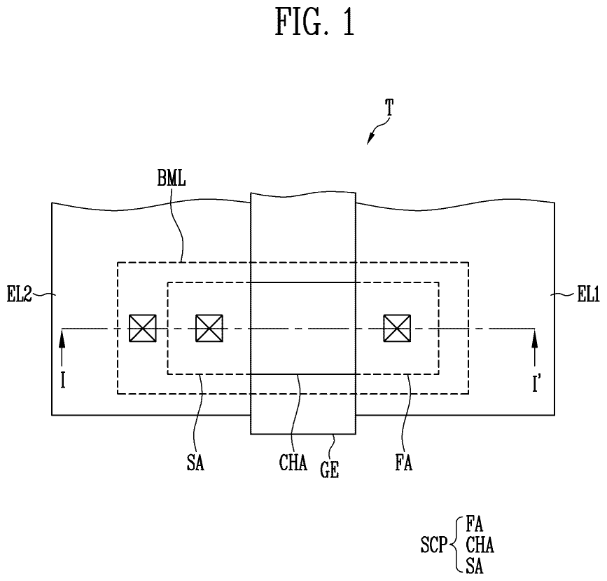

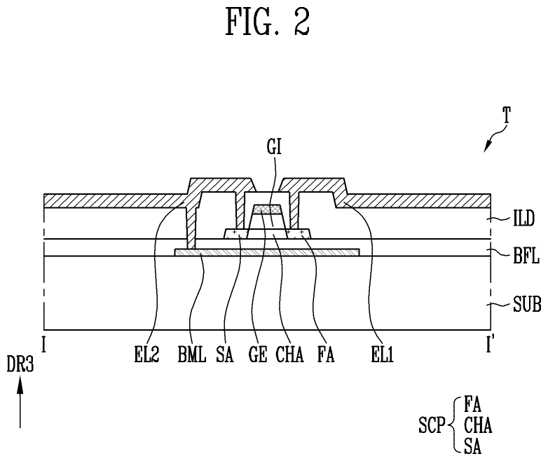

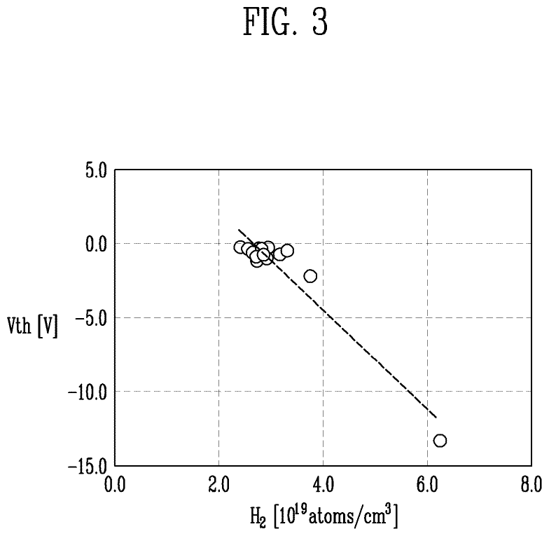

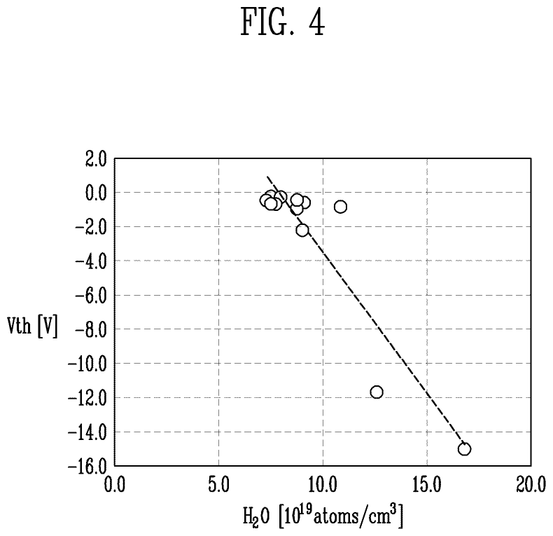

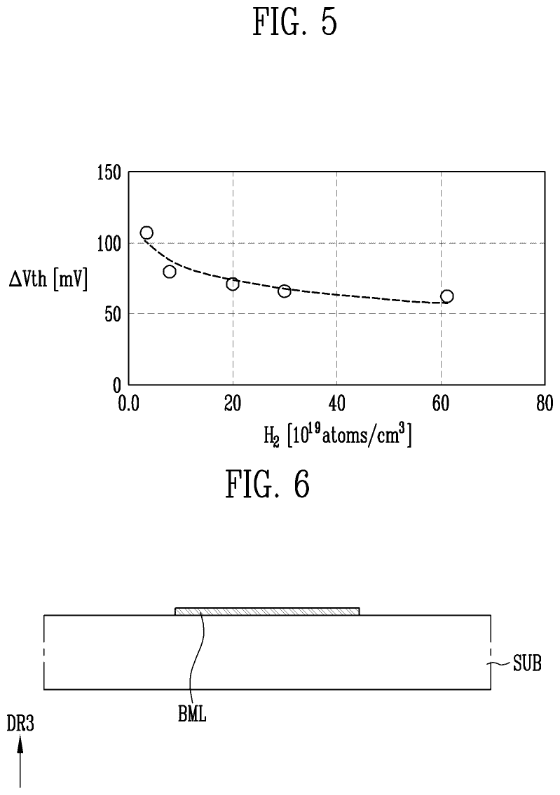

FIG. 1 is a schematic plan view illustrating a transistor in accordance with an embodiment of the present disclosure. FIG. 2 is a schematic sectional view taken along line I-I′ shown in FIG. 1. FIG. 3 is a graph illustrating threshold voltage of the transistor according to concentration of hydrogen gas (H₂) discharged from a buffer layer at a temperature of 400° C. In the graph shown in FIG. 3, the X axis represents concentration of hydrogen gas (H₂) discharged from a buffer layer BFL and the concentration has a unit of 10¹⁹ atoms (or molecules)/cm³. The Y axis represents threshold voltage in initial driving of a transistor T and the threshold voltage has a unit of volt (V). FIG. 4 is a graph illustrating threshold voltage of the transistor according to concentration of moisture (H₂O) discharged from the buffer layer at a temperature of 400° C. In the graph shown in FIG. 4, the X axis represents concentration of moisture (H₂O) discharged from the buffer layer BFL and the concentration has a unit of 10¹⁹ atoms (or molecules)/cm³. The Y axis represents threshold voltage in initial driving of the transistor T and the threshold voltage has a unit of volt (V). FIG. 5 is a graph illustrating threshold voltage difference value of the transistor according to concentration of hydrogen gas (H₂) discharged from a gate insulating layer at a temperature of 400° C. In the graph shown in FIG. 5, the X axis represents concentration of hydrogen gas (H₂) discharged from a gate insulating layer GI and the concentration has a unit of 10¹⁹ atoms (or molecules)/cm³. The Y axis represents difference value between threshold voltages in initial driving of the transistor T and after driving of the transistor T, and the difference value has a unit of millivolt (mV).

For convenience of description, in the present disclosure, directions in which a plane on which the transistor T is disposed extends is indicated as a first direction DR1 and a second direction DR2, and a vertical direction is indicated as a third direction DR3.

Referring to FIGS. 1 and 2, the transistor T in accordance with the embodiment of the present disclosure may include a gate electrode GE, a semiconductor layer SCP, a source electrode (e.g., one of a first electrode EL1 and a second electrode EL2), and a drain electrode (e.g., the other of the first electrode EL1 and the second electrode EL2). In some embodiments, the transistor T may have a bottom metal pattern BML. The transistor T in accordance with the present disclosure may be a transistor including an oxide semiconductor as an active layer.

The semiconductor layer SCP may be disposed on the buffer layer BFL and include a first region FA, a second region SA, and a channel region CHA (or third region disposed between the first region FA and the second region SA. In an embodiment, the first region FA and a second region SA may be doped with an impurity to have conductivity. The channel region CHA may be an intrinsic semiconductor layer which overlaps with the gate electrode GE and is undoped with the impurity.

The channel region CHA may be a region overlapping with the gate electrode GE. The first region FA may be in contact with one end of the channel region CHA and be electrically connected to the first electrode EL1. The second region SA may be in contact with the other end of the channel region CHA and be electrically connected to the second electrode EL2.

In an embodiment, the semiconductor layer SCP may include an oxide semiconductor. In an example, the semiconductor layer SCP may include an oxide semiconductor including at least one of indium (In), zinc (Zn), gallium (Ga), tin (Sn), titanium (Ti), aluminum (Al), hafnium (Hf), zirconium (Zr), and magnesium (Mg).

In an embodiment, the semiconductor layer SCP may include a rear surface (or lower surface) and a top surface which face each other in a thickness direction of a substrate SUB (e.g., the third direction DR3). The rear surface of the semiconductor layer SCP may be in contact with the buffer layer BFL and the top surface of the semiconductor layer SCP may be in contact with the gate insulating layer GI, the first electrode EL1, the second electrode EL2, and an interlayer insulating layer ILD.

The substrate SUB may include an insulative material such as glass, organic polymer, or quartz. The substrate SUB may be a rigid substrate or a flexible substrate. The rigid substrate may be, for example, one of a glass substrate, a quartz substrate, a glass ceramic substrate, and a crystalline glass substrate.

The flexible substrate may be one of a film substrate and a plastic substrate which include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

The buffer layer BFL may be disposed between the substrate SUB and the semiconductor layer SCP. The buffer layer BFL may be disposed under the semiconductor layer SCP.

The buffer layer BFL (or first insulating layer) may be disposed on the substrate SUB. The buffer layer BFL may prevent an impurity from being diffused into the semiconductor layer SCP. The buffer layer BFL may be an inorganic insulating layer including an inorganic material. The buffer layer BFL may include at least one of silicon nitride (SiNₓ), silicon oxide (SiOₓ), and silicon oxynitride (SiOₓN_{y}), or include at least one of metal oxides such as aluminum oxide (AlOₓ). In an embodiment, the buffer layer BFL may include silicon oxide (SiOₓ). The buffer layer BFL may be provided as a single layer, but be provided as a multi-layer including at least two layers. When the buffer layer BFL is provided as the multi-layer, the layers may be formed of the same material or be formed of different materials.

The buffer layer BFL may contain hydrogen (H). A concentration of hydrogen (H) in the buffer layer BFL may be 4×10²⁰ atoms/cm³ to 20×10²⁰ atoms/cm³.

The buffer layer BFL may discharge hydrogen gas (H₂) of 1×10¹⁹ atoms (or molecules)/cm³ to 10×10¹⁹ atoms (or molecules)/cm³ at a temperature of 350° C. to 450° C. For example, the buffer layer BFL may discharge hydrogen gas (H₂) of 1×10¹⁹ atoms/cm³ to 10×10¹⁹ atoms/cm³ at a temperature of 400° C.

In an embodiment, the buffer layer BFL may discharge hydrogen gas (H₂) of 1×10¹⁹ atoms/cm³ to 5×10¹⁹ atoms/cm³ at a temperature of 400° C. In an embodiment, the buffer layer BFL may discharge hydrogen gas (H₂) of 1×10¹⁹ atoms/cm³ to 4×10¹⁹ atoms/cm³ at a temperature of 400° C.

As the buffer layer BFL includes hydrogen (H) as much as the above-described numerical value range, the transistor T in accordance with the present disclosure may discharge hydrogen gas (H₂) as much as the above-described numerical value range at a temperature of 400° C. Accordingly, the transistor T can have a target threshold voltage and have high reliability. Hereinafter, in the present disclosure, the target threshold voltage of the transistor T may be about −2.5 V. In an example, the target threshold voltage of the transistor T may be 0 V to −3.5 V. Experimentally, the transistor T may preferably have a threshold voltage of 0 V to −3.5 V so as to have high reliability while not excessively increasing a driving current.

Referring to FIG. 3, it can be seen that, as hydrogen gas (H₂) is discharged as much as 1×10¹⁹ atoms/cm³ to 10×10¹⁹ atoms/cm³ from the buffer layer BFL, the transistor T substantially has a threshold voltage of 0 V to −3.5 V.

In an embodiment, the buffer layer BFL may discharge moisture (H₂O) of 1×10¹⁹ atoms (or molecules)/cm³ to 20×10¹⁹ atoms (or molecules)/cm³ at a temperature of 350° C. to 450° C. For example, the buffer layer BFL may discharge moisture (H₂O) of 1×10¹⁹ atoms/cm³ to 20×10¹⁹ atoms/cm³ at a temperature of 400° C. Hereinafter, in the present disclosure, moisture (H₂O) discharged at a temperature of 350° C. to 450° C. may be discharged in the form of gas, for example, water vapor.

In an embodiment, the buffer layer BFL may discharge moisture (H₂O) of 1×10¹⁹ atoms/cm³ to 10×10¹⁹ atoms/cm³ at a temperature of 400° C. In an embodiment, the buffer layer BFL may discharge moisture (H₂O) of 5×10¹⁹ atoms/cm³ to 10×10¹⁹ atoms/cm³ at a temperature of 400° C. In an embodiment, the buffer layer BFL may discharge moisture (H₂O) of 6×10¹⁹ atoms/cm³ to 10×10¹⁹ atoms/cm³ at a temperature of 400° C. As the buffer layer BFL discharges as much as the above-described numerical value range at a temperature of 400° C., the transistor T in accordance with the present disclosure can have the target threshold voltage and have high reliability.

Referring to FIG. 4, it can be seen that, as the moisture (H₂O) is discharged as much as 1×10¹⁹ atoms/cm³ to 20×10¹⁹ atoms/cm³ from the buffer layer BFL, the transistor T substantially has a threshold voltage of 0 V to −3.5 V.

At a temperature of 400° C., as a larger amount of hydrogen gas (H₂) and moisture (H₂O) is discharged from an insulating layer of the transistor T, the threshold voltage of the transistor T may have a negative value. However, when the threshold voltage of the transistor T has an excessively large negative value, the driving current is increased, and therefore, the reliability of the transistor T may be deteriorated. Accordingly, the transistor T may preferably have a threshold voltage of 0 V to −3.5 V.

In an embodiment, the buffer layer BFL may discharge hydrogen gas (H₂) and moisture (H₂O) as much as the above-described numerical value range, and the transistor T may have a threshold voltage of 0 V to −3.5 V. Thus, the reliability of the transistor T can be improved.

In an embodiment, the bottom metal pattern BML may be disposed between the substrate SUB and the buffer layer BFL.

The bottom metal pattern BML may be a first conductive layer located between the substrate SUB and the buffer layer BFL. The bottom metal pattern BML may be electrically connected to the second electrode EL2 through a contact hole sequentially penetrating the interlayer insulating layer ILD and the buffer layer BFL. The range of a predetermined voltage supplied to the gate electrode GE of the transistor T may be widened. As the bottom metal pattern BML is electrically connected to the second electrode EL2, the channel region CHA of the semiconductor layer SCP can be stabilized. In addition, as the bottom metal pattern BML is electrically connected to the second electrode EL2, floating of the bottom metal pattern BML can be prevented.

The bottom metal pattern BML may be formed as a single layer including one appropriate (or selected) from the group consisting of copper (Cu), molybdenum (Mo), tungsten (W), aluminum neodymium (AlNd), titanium (Ti), aluminum (Al), silver (Ag), and any alloy thereof or a mixture thereof, or be formed in a double- or multi-layer structure including molybdenum (Mo), titanium (Ti), copper (Cu), aluminum (Al) or silver (Ag), which is a low-resistance material so as to decrease wiring resistance. In an embodiment, the bottom metal pattern BML may include aluminum (Al).

In an embodiment, the bottom metal pattern BML may overlap with the semiconductor layer SCP. The bottom metal pattern BML may be used as a light blocking member for blocking light which may be introduced from a rear surface of the substrate SUB, thereby protecting the transistor T. To this end, the bottom metal pattern BML may be configured with a light blocking material and/or a light absorbing material. In an example, the bottom metal pattern BML may be configured as an opaque metal layer.

The gate insulating layer GI may be disposed on the semiconductor layer SCP. The gate insulating layer GI may be disposed between the semiconductor layer SCP and the gate electrode GE.

The gate insulating layer GI (or second insulating layer) may include the same material as the buffer layer BFL or include an appropriate (or selected) material among the materials exemplified as the material constituting the buffer layer BFL. In an example, the gate insulating layer GI may be an inorganic insulating layer including an inorganic material.

The gate insulating layer GI may contain hydrogen (H). A concentration of hydrogen (H) in the gate insulating layer GI may be 5×10²⁰ atoms/cm³ to 30×10²⁰ atoms/cm³.

The gate insulating layer GI may discharge a large amount of hydrogen gas (H₂) as compared with the buffer layer BFL at a temperature of 350° C. to 450° C. The gate insulating layer GI may discharge hydrogen gas (H₂) of 10×10¹⁹ atoms (or molecules)/cm³ to 60×10¹⁹ atoms (or molecules)/cm³ at a temperature of 350° C. to 450° C. For example, the gate insulating layer GI may discharge hydrogen gas (H₂) of 10×10¹⁹ atoms/cm³ to 60×10¹⁹ atoms/cm³ at a temperature of 400° C.

As the gate insulating layer GI includes hydrogen (H) as much as the above-described numerical value range, the transistor T in accordance with the present disclosure may discharge hydrogen gas (H₂) as much as the above-described numerical value range at a temperature of 400° C. from the gate insulating layer GI. Accordingly, the transistor T can have high reliability. In order for the transistor T to have high reliability, the difference value between the threshold voltages in the initial driving of the transistor T and after the driving of the transistor T may be preferably with 75 mV.

Referring to FIG. 5, it can be seen that, as hydrogen gas (H₂) is discharged as much as 10×10¹⁹ atoms/cm³ to 60×10¹⁹ atoms/cm³ from the gate insulating layer GI, the difference value between the threshold voltages of the transistor T is within 75 mV.

As the gate insulating layer GI includes hydrogen (H) as much as the above-described numerical value range, the transistor T in accordance with the present disclosure may discharge hydrogen gas (H₂) as much as the above-described numerical value range from the gate insulating layer GI at a temperature of 400° C. from the gate insulating layer GI. Accordingly, the transistor T can have high reliability.

The gate electrode GE may be disposed on the gate insulating layer GI.

The gate electrode GE may overlap with the channel region CHA of the semiconductor layer SCP with the gate insulating layer GI interposed therebetween. The gate electrode GE may be made of a conductive material, e.g., a metal. For example, the gate electrode GE may include at least one of copper (Cu), molybdenum (Mo), tungsten (W), aluminum neodymium (ALNd), titanium (Ti), aluminum (Al), silver (Ag), and alloys thereof. In an embodiment, the gate electrode GE may include aluminum (Al). The gate electrode GE may serve as a doping prevention layer for allowing an impurity not to be doped into the channel region CHA. The gate electrode GE may define the channel region CHA of the semiconductor layer SCP.

The interlayer insulating layer ILD may be disposed over the gate electrode GE.

The interlayer insulating layer ILD (or third insulating layer) may be entirely provided and/or formed over the gate electrode GE and the buffer layer BFL. The interlayer insulating layer ILD may include the same material as the buffer layer BFL or include an appropriate (or selected) material among the materials exemplified as the material constituting the buffer layer BFL. In an example, the interlayer insulating layer ILD may be an inorganic insulating layer including an inorganic material, but the present disclosure is not limited thereto. In some embodiments, the interlayer insulating layer ILD may be an organic insulating layer including an organic material. The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin.

The interlayer insulating layer ILD may contain hydrogen (H). In an embodiment, a concentration of hydrogen (H) in the interlayer insulating layer ILD may be 4×10²⁰ atoms/cm³ to 20×10²⁰ atoms/cm³.

The interlayer insulating layer ILD may discharge hydrogen gas (H₂) of 1×10¹⁹ atoms (or molecules)/cm³ to 10×10¹⁹ atoms (or molecules)/cm³ at a temperature of 350° C. to 450° C. For example, the interlayer insulating layer ILD may discharge hydrogen gas (H₂) of 1×10¹⁹ atoms/cm³ to 10×10¹⁹ atoms/cm³ at a temperature of 400° C.

In an embodiment, the interlayer insulating layer ILD may discharge hydrogen gas (H₂) of 1×10¹⁹ atoms/cm³ to 7×10¹⁹ atoms/cm³ at a temperature of 400° C. In an embodiment, the interlayer insulating layer ILD may discharge hydrogen gas (H₂) of 1×10¹⁹ atoms/cm³ to 6×10¹⁹ atoms/cm³ at a temperature of 400° C.

As the interlayer insulating layer ILD includes hydrogen (H) as much as the above-described numerical value range, the transistor T in accordance with the present disclosure may discharge hydrogen gas (H₂) as much as the above-described numerical value range from the interlayer insulating layer ILD. Accordingly, the interlayer insulating layer ILD can have a sheet resistance of 1200 Ω/sq or less, and the transistor T can have high reliability. Experimentally, the transistor T may preferably have a sheet resistance of 1200 Ω/sq or less so as to have high reliability.

The first electrode EL1 and the second electrode EL2 may be disposed on the interlayer insulating layer ILD.

The first electrode EL1 may be located on the interlayer insulating layer ILD to overlap with the first region FA of the semiconductor layer SCP and be electrically connected to the first region FA of the semiconductor layer SCP through a contact hole penetrating one region of the interlayer insulating layer ILD. The second electrode EL2 may be located on the interlayer insulating layer ILD to overlap with the second region SA of the semiconductor layer SCP, and be electrically connected to the second region SA of the semiconductor layer SCP through a contact hole penetrating another region of the interlayer insulating layer ILD.

The first electrode EL1 and the second electrode EL2 may be disposed on the interlayer insulating layer ILD over the gate electrode GE to be spaced apart from each other. One of the first electrode EL1 and the second electrode EL2 may be a source electrode and the other of the first electrode EL1 and the second electrode EL2 may be a drain electrode.

Each of the first and second electrodes EL1 and EL2 may include a conductive material, e.g., a metal. Each of the first and second electrodes EL1 and EL2 may include the same material as the bottom metal pattern BML or include at least one material appropriate (or selected) from the materials exemplified as the material constituting the bottom metal pattern BML.

A passivation layer for protecting the first and second electrodes EL1 and EL2 may be provided over the first and second electrodes EL1 and EL2.

FIGS. 6 to 12 are schematic sectional views illustrating a manufacturing method of a transistor in accordance with an embodiment of the present disclosure.

Hereinafter, the transistor in accordance with the embodiment of the present disclosure will be sequentially described according to the manufacturing method with reference to FIGS. 6 to 12.

In an embodiment, although it is described that manufacturing steps of the transistor are sequentially performed according to the sectional views, without changing the spirit of the present disclosure, some steps illustrated as being successively performed may be simultaneously performed, the sequence of the steps may be changed, some steps may be omitted, or another step may be further included between the steps.

Referring to FIG. 6, the manufacturing method of the transistor T may include a step of forming a bottom metal pattern BML on a substrate SUB.

The substrate SUB may be a glass substrate. However, the substrate SUB may be one of other substrate, e.g., various substrates used in an ordinary semiconductor element process such as a plastic substrate and a silicon substrate.

The bottom metal pattern BML may be formed by forming a conductive layer through a process of depositing a conductive material on one surface (or top surface) of the substrate SUB, and patterning the formed conductive layer through a process such as photolithography using a mask. The conductive material may be a single layer of metal or multiple layers of metals or alloys thereof, but the present disclosure is not limited thereto.

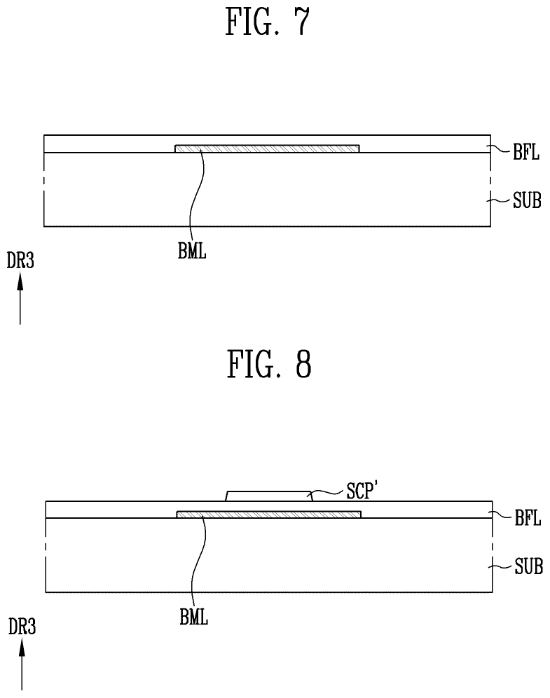

Referring to FIG. 7, the manufacturing method of the transistor T may include a step of forming a buffer layer BFL on the bottom metal pattern BML and the substrate SUB.

The step of forming the buffer layer BFL may include a step of forming the buffer layer BFL such that a concentration of hydrogen (H) in the buffer layer BFL is 4×10²⁰ atoms/cm³ to 20×10²⁰ atoms/cm³. The concentration of hydrogen (H) in the buffer layer BFL may be adjusted by adjusting process conditions such as a temperature of a chamber in which deposition of the buffer layer BFL is performed, a partial pressure of oxygen in the chamber, and a deposition time.

The step of forming the buffer layer BFL may include a step of forming the buffer layer BFL to discharge hydrogen gas (H₂) of 1×10¹⁹ atoms/cm³ to 10×10¹⁹ atoms/cm³ at a temperature of 350° C. to 450° C. For example, the step of forming the buffer layer BFL may include a step of forming the buffer layer BFL to discharge hydrogen gas (H₂) of 1×10¹⁹ atoms/cm³ to 10×10¹⁹ atoms/cm³ at a temperature of 400° C.

In an embodiment, the step of forming the buffer layer BFL may include a step of forming the buffer layer BFL to discharge hydrogen gas (H₂) of 1×10¹⁹ atoms/cm³ to 5×10¹⁹ atoms/cm³ at a temperature of 400° C. In an embodiment, the step of forming the buffer layer BFL may include a step of forming the buffer layer BFL to discharge hydrogen gas (H₂) of 1×10¹⁹ atoms/cm³ to 4×10¹⁹ atoms/cm³ at a temperature of 400° C.

The step of forming the buffer layer BFL may include a step of forming the buffer layer to discharge moisture (H₂O) of 1×10¹⁹ atoms/cm³ to 20×10¹⁹ atoms/cm³ at a temperature of 350° C. to 450° C. For example, the step of forming the buffer layer BFL may include a step of forming the buffer layer BFL to discharge moisture (H₂O) of 1×10¹⁹ atoms/cm³ to 20×10¹⁹ atoms/cm³ at a temperature of 400° C.

In an embodiment, the step of forming the buffer layer BFL may include a step of forming the buffer layer BFL to discharge moisture (H₂O) of 1×10¹⁹ atoms/cm³ to 10×10¹⁹ atoms/cm³ at a temperature of 400° C. In an embodiment, the step of forming the buffer layer BFL may include a step of forming the buffer layer BFL to discharge moisture (H₂O) of 5×10¹⁹ atoms/cm³ to 10×10¹⁹ atoms/cm³ at a temperature of 400° C. In an embodiment, the step of forming the buffer layer BFL may include a step of forming the buffer layer BFL to discharge moisture (H₂O) of 6×10¹⁹ atoms/cm³ to 10×10¹⁹ atoms/cm³ at a temperature of 400° C.

The buffer layer BFL may be formed by a Chemical Vapor Deposition (CVD) method or a sputtering method using a gas including silane and nitrogen oxide (N₂O), but the method of forming the buffer layer BFL is not limited thereto.

In an embodiment, the buffer layer BFL may be provided in the form of a multi-layer including a double layer. In an example, when the buffer layer BFL is provided as a double layer including a first layer and a second layer, which are sequentially stacked, the first layer and the second layer may be formed of different materials among inorganic materials, and be formed through different processes. However, the present disclosure is not limited thereto. In some embodiments, the first layer and the second layer may include the same material and be formed through a continuous process.

In an embodiment, a heat treatment process may be performed after the buffer layer BFL is formed. The concentration of hydrogen (H) of the buffer layer BFL may be adjusted through the heat treatment process, and a hydrogen (H) content of the buffer layer BFL, which minimizes influence on the semiconductor layer SCP (or defect of the semiconductor layer SCP), may be optimized.

Referring to FIG. 8, the manufacturing method of the transistor T may include a step of forming a buffer semiconductor layer SCP′. After a base oxide semiconductor layer (not shown) is formed on the buffer layer BFL, the base oxide semiconductor layer may be patterned through a photolithography process using a mask, thereby forming the buffer semiconductor layer SCP′. The buffer semiconductor layer SCP′ may be an intrinsic semiconductor undoped with an impurity.

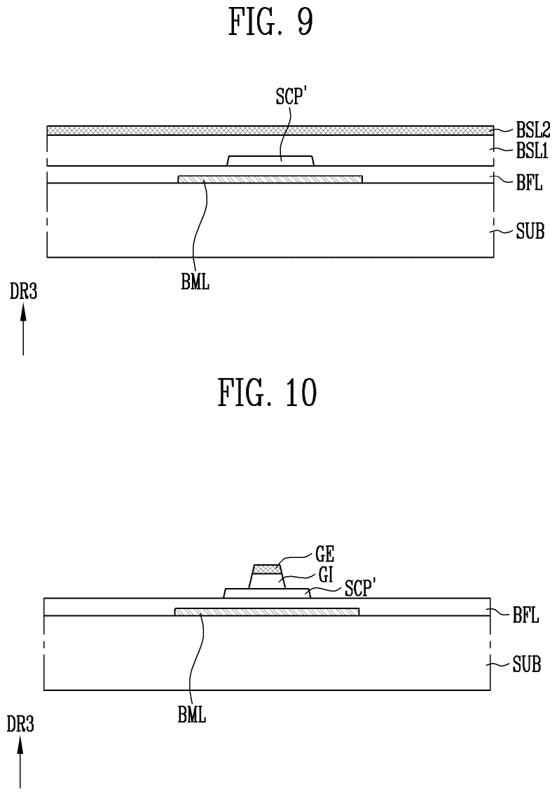

Referring to FIGS. 9 and 10, the manufacturing method of the transistor T may include a step of forming a gate insulating layer GI and a gate electrode GE on the buffer semiconductor layer SCP′.

The step of forming the gate insulating layer GI and the gate electrode GE may include a step of sequentially forming a first base layer BSL1 and a second base layer BSL2 on the buffer semiconductor layer SCP′ and the buffer layer BFL using at least one of a Chemical Vapor Deposition (CVD) method and a sputtering method.

In some embodiments, the gate insulating layer GI may be formed by a Chemical Vapor Deposition (CVD) method or a sputtering method using a gas including silane and nitrogen oxide (N₂O), but the method of forming the gate insulating layer GI is not limited thereto.

The first base layer BSL1 may be a base material of the gate insulating layer GI. The first base layer BSL1 may be etched to form the gate insulating layer GI. The second base layer BSL2 may be a base material of the gate electrode GE. The second base layer BSL2 may be etched to form the gate electrode GE.

In an embodiment, after forming the first base layer BSL1, surface treatment may be performed. The surface treatment may include a heat treatment process, e.g., an annealing process.

The step of forming the gate insulating layer GI and the gate electrode GE may include a step of forming the gate insulating layer GI and the gate electrode GE by etching the first base layer BSL1 and the second base layer BSL2. The second base layer BSL2 may be patterned by performing a photolithography process using a mask, and, accordingly, the gate electrode GE may be formed. The gate electrode GE may overlap with a portion of the buffer semiconductor layer SCP′. In an example, the gate electrode GE may overlap with a middle region of the buffer semiconductor layer SCP′. Both end portions of the buffer semiconductor layer SCP′ may not be covered by the gate electrode GE.

In the photolithography process of forming the gate electrode GE, a portion of the first base layer BSL1 may be removed using the gate electrode GE as an etch mask, thereby forming the gate insulating layer GI. The gate insulating layer GI may have a width substantially equal or similar to a width of the gate electrode GE, but the present disclosure is not limited thereto. The gate electrode GE and the gate insulating layer GI may overlap with each other.

The step of forming the gate insulating layer GI may include a step of forming the gate insulating layer GI such that a concentration of hydrogen (H) in the gate insulating layer GI is 5×10²⁰ atoms/cm³ to 30×10²⁰ atoms/cm³. The concentration of hydrogen (H) in the gate insulating layer GI may be adjusted by adjusting process conditions such as a temperature of a chamber in which deposition of the gate insulating layer GI is performed, a partial pressure of oxygen in the chamber, and a deposition time.

The step of forming the gate insulating layer GI may include a step of forming the gate insulating layer GI such that the gate insulating layer GI discharges hydrogen gas (H₂) of 10×10¹⁹ atoms/cm³ to 60×10¹⁹ atoms/cm³ at a temperature of 350° C. to 450° C. For example, the step of forming the gate insulating layer GI may include a step of forming the gate insulating layer GI such that the gate insulating layer GI discharges hydrogen gas (H₂) of 10×10¹⁹ atoms/cm³ to 60×10¹⁹ atoms/cm³ at a temperature of 400° C.

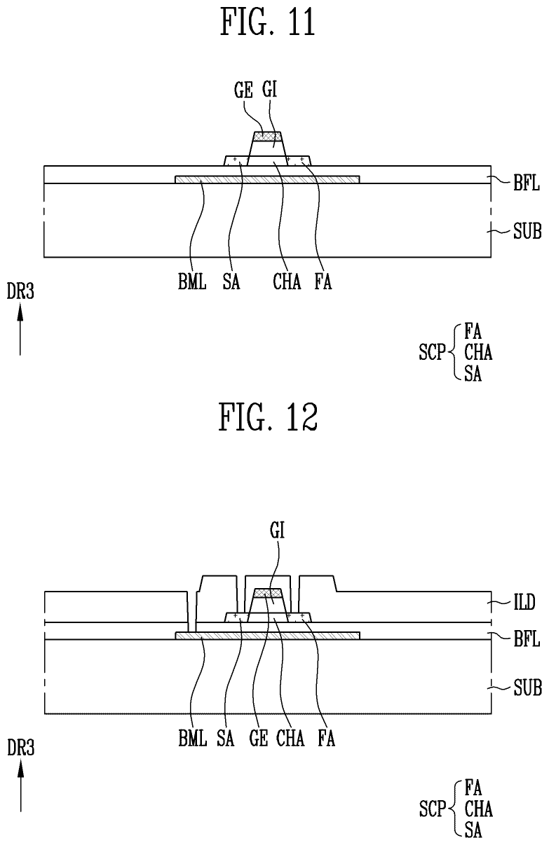

Referring to FIG. 11, the manufacturing method of the transistor T may include a step of forming a semiconductor layer SCP. An impurity may be doped into portions of the buffer semiconductor layer SCP′ which are not covered by the gate electrode GE and the semiconductor layer SCP including a first region FA and a second region SA which have conductivity may be formed.

The semiconductor layer SCP may include a channel region CHA which is located between the first region FA and the second region SA and is undoped with the impurity while overlapping with the gate electrode GE.

Referring to FIG. 12, the manufacturing method of the transistor T may include a step of forming an interlayer insulating layer ILD on the gate electrode GE, the semiconductor layer SCP, and the buffer layer BFL.

The interlayer insulating layer ILD may be formed by a Chemical Vapor Deposition (CVD) method or a sputtering method using a gas including silane and nitrogen oxide (N₂O), but the method of forming the interlayer insulating layer ILD is not limited thereto.

The interlayer insulating layer ILD may be an inorganic insulating layer including an inorganic material or an organic insulating layer including an organic material. In the step of forming the interlayer insulating layer ILD, the interlayer insulating layer ILD may be partially removed in areas corresponding to the first region FA of the semiconductor layer SCP, the second region SA of the semiconductor layer SCP, and one region of the bottom metal pattern BML.

The step of forming the interlayer insulating layer ILD may include a step of forming the interlayer insulating layer ILD such that a concentration of hydrogen (H) in the interlayer insulating layer ILD is 4×10²⁰ atoms/cm³ to 20×10²⁰ atoms/cm³. The concentration of hydrogen (H) in the interlayer insulating layer ILD may be adjusted by adjusting process conditions such as a temperature of a chamber in which deposition of the interlayer insulating layer ILD is performed, a partial pressure of oxygen in the chamber, and a deposition time.

The step of forming the interlayer insulating layer ILD may include a step of forming the interlayer insulating layer ILD such that the interlayer insulating layer ILD discharges hydrogen gas (H₂) of 1×10¹⁹ atoms/cm³ to 10×10¹⁹ atoms/cm³ at a temperature of 350° C. to 450° C. For example, the step of forming the interlayer insulating layer ILD may include a step of forming the interlayer insulating layer ILD such that the interlayer insulating layer ILD discharges hydrogen gas (H₂) of 1×10¹⁹ atoms/cm³ to 10×10¹⁹ atoms/cm³ at a temperature of 400° C.

In an embodiment, the step of forming the interlayer insulating layer ILD may include a step of forming the interlayer insulating layer ILD such that the interlayer insulating layer ILD discharges hydrogen gas (H₂) of 1×10¹⁹ atoms/cm³ to 7×10¹⁹ atoms/cm³ at a temperature of 400° C. In an embodiment, the step of forming the interlayer insulating layer ILD may include a step of forming the interlayer insulating layer ILD such that the interlayer insulating layer ILD discharges hydrogen gas (H₂) of 1×10¹⁹ atoms/cm³ to 6×10¹⁹ atoms/cm³ at a temperature of 400° C.

After the interlayer insulating layer ILD is formed, a process of forming a first electrode EL1 (see FIG. 2) and a second electrode EL2 (see FIG. 2) on the interlayer insulating layer ILD to be spaced apart from each other is performed. The first electrode EL1 may be electrically connected to the first region FA of the semiconductor layer SCP, and the second electrode EL2 may be electrically connected to the second region SA of the semiconductor layer SCP.

The transistor T manufactured through the above-described processes may be employed in various electronic elements. Hence, the transistor T may be employed in, for example, a display device. The display device may include a light emitting element, and a transistor electrically connected to the light emitting element, and the transistor T in accordance with the above-described embodiment may be employed as the transistor.

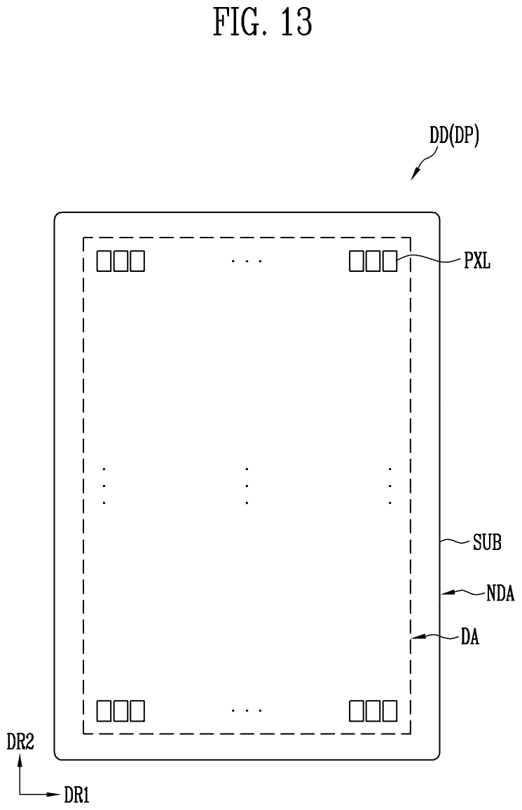

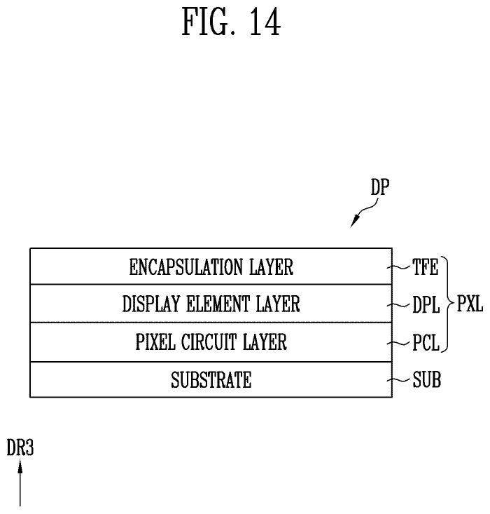

FIG. 13 is a schematic plan view illustrating a display device in accordance with an embodiment of the present disclosure. FIG. 14 is a schematic sectional view illustrating a display panel shown in FIG. 13.

In FIGS. 13 and 14, for convenience of description, a structure of a display device DD, particularly, a display panel DP provided in the display device DD is briefly illustrated based on a display area DA in which an image is displayed.

Referring to FIGS. 13 and 14, the display panel DP (or the display device DD) in accordance with the embodiment of the present disclosure may include a substrate SUB, pixels PXL disposed on the substrate SUB, a driver which is provided on the substrate SUB and drives the pixels PXL, and a line portion connecting the pixels PXL and the driver to each other.

The substrate SUB may include a transparent insulating material to enable light to be transmitted therethrough. The substrate SUB may be a rigid substrate or a flexible substrate. The substrate SUB may include the same material as the substrate SUB described with reference to FIGS. 1 and 2.

One area on the substrate SUB may be provided as the display area DA such that the pixels PXL are disposed therein, and the other area on the substrate SUB may be provided as a non-display area NDA. In an example, the substrate SUB may include the display area DA including pixel areas in which the respective pixels PXL are disposed and the non-display area NDA disposed at the periphery of the display area DA (or adjacent to the display area DA).

The display area DA may have various shapes. For example, the display area DA may be provided in various shapes such as a closed polygonal including linear sides, a circle, an ellipse or the like including a curved side, and a semicircle, a semi-ellipse or the like including linear and curved sides.

The non-display area NDA may be provided at at least one side of the display area DA. In an example, the non-display area NDA may surround a circumference of the display area DA. The driver for driving the pixels PXL and a portion of the line portion (e.g., fan-out lines) connecting the pixels PXL and the driver to each other may be provided in the non-display area NDA. The non-display area NDA may correspond to a bezel area of the display device DD.

The pixels PXL may be provided in the display area DA of the substrate SUB. Each of the pixels PXL may be a minimum unit for displaying an image. Each of the pixels PXL may include a light emitting element emitting white light and/or colored light. Each of the pixels PXL may emit light of any one color among red, green, and blue. However, the present disclosure is not limited thereto, and each of the pixels PXL may emit light of a color including cyan, magenta, yellow, and the like.

The pixels PXL may be arranged in a matrix form along rows (or pixel rows) extending in the first direction DR1 and columns (or pixel columns) extending in the second direction DR2 intersecting the first direction DR1. However, the arrangement form of the pixels PXL is not particularly limited, and the pixels PXL may be arranged in various forms. Although a case where the pixels PXL have a rectangular shape is illustrated in the drawings, the present disclosure is not limited thereto, and the pixels PXL may be modified to have various shapes. In addition, when each pixel PXL is provided in plurality, the plurality of pixels PXL may be provided to have different areas (or sizes). For example, in the case of pixels PXL emitting lights of different colors, the pixels PXL with respect to the different colors may be provided in different areas (or sizes) or different shapes.

The driver may provide signals and power to each pixel PXL through the line portion, thereby controlling driving of the pixel PXL.

Each pixel PXL may include a pixel circuit layer PCL, a display element layer DPL, and an encapsulation layer TFE, which are located on the substrate SUB.

The pixel circuit layer PCL may be provided on the substrate SUB, and include a plurality of transistors and signal lines connected to the transistors. For example, each transistor may have a form in which a semiconductor layer, a gate electrode, a first terminal, and a second terminal are sequentially stacked with an insulating layer interposed therebetween. The semiconductor layer may include an oxide semiconductor. The gate electrode, the first terminal, and the second terminal may include one of aluminum (Al), copper (Cu), titanium (Ti), and molybdenum (Mo), but the present disclosure is not limited thereto. Also, the pixel circuit layer PCL may include at least one insulating layer.

The display element layer DPL may be disposed on the pixel circuit layer PCL. The display element layer DPL may include a light emitting element emitting light. The light emitting element may be, for example, an organic light emitting diode, but the present disclosure is not limited thereto. In some embodiments, the light emitting element may be an inorganic light emitting element including an inorganic light emitting material or a light emitting element emitting light by changing a wavelength of light emitted using a quantum dot.

The encapsulation layer TFE may be disposed on the display element layer DPL. The encapsulation layer TFE may be an encapsulation substrate or have the form of an encapsulation layer provided as a multi-layer. When the encapsulation layer TFE has the form of the encapsulation layer, the encapsulation layer TFE may include an inorganic layer and/or an organic layer. For example, the encapsulation layer TFE may have a form in which an inorganic layer, an organic layer, and an inorganic layer are sequentially stacked. The encapsulation layer TFE may prevent external air and moisture from infiltrating into the display element layer DPL and the pixel circuit layer PCL.

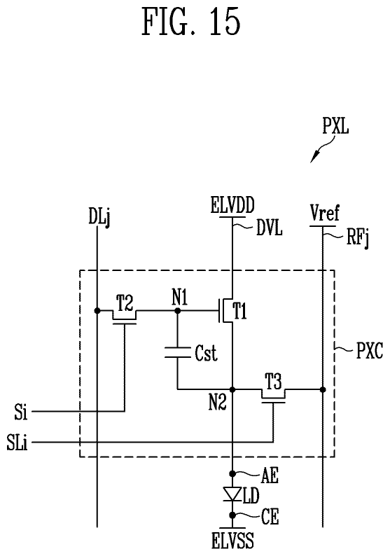

FIG. 15 is a schematic circuit diagram illustrating an electrical connection relationship of components included in each of the pixels shown in FIG. 13.

Referring to FIGS. 13 to 15, the pixel PXL may include a light emitting element LD and a pixel circuit PXC electrically connected to the light emitting element LD to drive the light emitting element LD.

A pixel electrode AE (or anode electrode) of the light emitting element LD may be electrically connected to the pixel circuit PXC. The light emitting element LD generates light with a predetermined luminance corresponding to an amount of current supplied from the pixel circuit PXC. To this end, a second driving power source ELVSS electrically connected to a common electrode CE (or cathode electrode) of the light emitting element LD may be set to a voltage lower than a voltage of a first driving power source ELVDD during a driving period of the display device DD, but the present disclosure is not limited thereto.

When the pixel PXL is located on an i^{th} row and a j^{th} column in the display area DA, the pixel circuit PXC of the pixel PXL may be electrically connected to an i^{th} scan line Si and a j^{th} data line DLj. Also, the pixel circuit PXC may be electrically connected to an i^{th} sensing line SLi and a j^{th} reference voltage line RFj.

The pixel circuit PXC may control an amount of current flowing from the first driving power source ELVDD to the second driving power source ELVSS via the light emitting element LD corresponding to a data signal (or data voltage).

The pixel circuit PXC may include first, second, and third transistors T1, T2, and T3 and a storage capacitor Cst.

The first transistor T1 is a driving transistor for controlling a driving current applied to the light emitting element LD and may be electrically connected between the first driving power source ELVDD and the light emitting element LD. Specifically, a first terminal of the first transistor T1 may be electrically connected to the first driving power source ELVDD through a driving voltage line DVL, a second terminal of the first transistor T1 may be electrically connected to a second node, and a gate electrode of the first transistor T1 may be electrically connected to a first node N1. The first transistor T1 may control an amount of driving current applied from the first driving power source ELVDD to the light emitting element LD through the second node N2 according to a voltage applied to the first node N1. In an embodiment, the first terminal of the first transistor T1 may be a drain electrode, and the second terminal of the first transistor T1 may be a source electrode. However, the present disclosure is not limited thereto. In some embodiments, the first terminal may be the source electrode and the second terminal may be the drain electrode.

The second transistor T2 may is a switching transistor which selects a pixel PXL and activates the pixel PXL, and may be electrically connected between the j^{th} data line DLj and the first node N1. A first terminal of the second transistor T2 may be electrically connected to the j^{th} data line DLj, a second terminal of the second transistor T2 may be electrically connected to the first node N1, and a gate electrode of the second transistor T2 may be electrically connected to the i^{th} scan line Si. The first terminal and the second terminal of the second transistor T2 are different terminals. For example, when the first terminal is a drain electrode and the second terminal may be a source electrode.

As such, the second transistor T2 may be turned on when a scan signal having a gate-on voltage (e.g., a high level voltage) is supplied from the i^{th} scan line Si to electrically connect the j^{th} data line DLj and the first node N1 to each other. The second transistor T2 may transfer a data signal to the gate electrode of the first transistor T1.

The third transistor T3 may be turned on when a sensing signal is supplied from the i^{th} sensing line SLi to electrically connect the j^{th} reference voltage line RFj to the first transistor T1 (or the second node N2). A first terminal of the third transistor T3 may be electrically connected to the j^{th} reference voltage line RFj, a second terminal of the third transistor T3 may be electrically connected to the second node N2, and a gate electrode of the third transistor T3 may be electrically connected to the i^{th} sensing line SLi.

The third transistor T3 may be a sensing transistor operated to supply a reference voltage Vref transferred through the j^{th} reference voltage line RFj to the second node N2 or to sense a voltage or current of the second node N2 or the j^{th} reference voltage line RFj. The reference voltage Vref may be a voltage, e.g., a voltage of an initialization power source, which is lower than the voltage of the first driving power source ELVDD and/or the data voltage.

The storage capacitor Cst may include a first storage electrode and a second storage electrode. The first storage electrode of the storage capacitor Cst may be electrically connected to the first node N1 and the second storage electrode of the storage capacitor Cst may be electrically connected to the second node N2. The storage capacitor Cst charges a data voltage corresponding to a data signal supplied to the first node N1 during one frame period. The storage capacitor Cst may store a voltage corresponding to a difference between a voltage of the gate electrode of the first transistor T1 and a voltage of the second node N2.

In an embodiment, at least one of the first, second, and third transistors T1, T2, and T3 included in the pixel circuit PXC may be an oxide transistor. At least one of the first, second, and third transistors T1, T2, and T3 may be the above-described transistor T. In an example, the transistor T may be the first transistor T1 described with reference to FIG. 15.

In an example, the first transistor T1 may be implemented as an NMOS transistor including an oxide semiconductor having a low off-current.

The structure of the pixel circuit PXC may be variously modified and embodied. In an example, the pixel circuit PXC may further include at least one transistor element such as a transistor element for initializing the first node N1 and/or a transistor element for controlling an emission time of the light emitting element LD, or other circuit elements such as a boosting capacitor for boosting a voltage of the first node N1. In an example, the pixel circuit PXC may include five transistor elements and two capacitors. In some embodiments, the pixel circuit may include seven transistor elements and two capacitors.

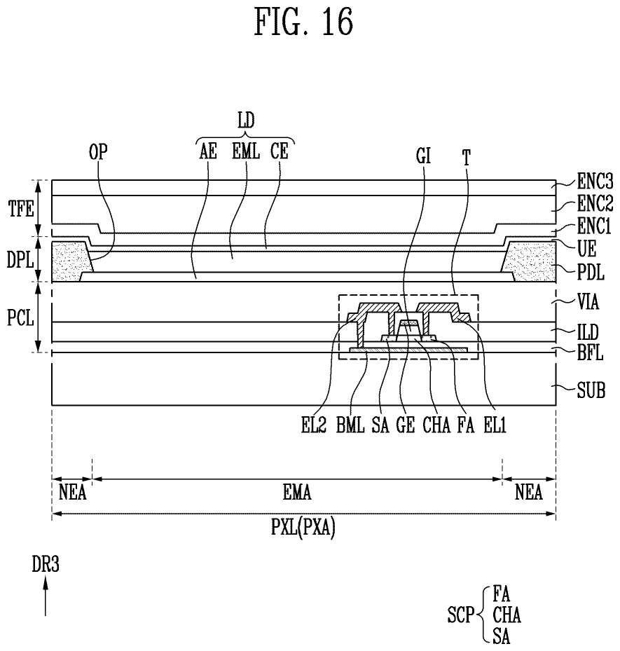

FIG. 16 is a schematic sectional view illustrating a pixel in accordance with an embodiment of the present disclosure.

Referring to FIGS. 13 to 16, the pixel PXL in accordance with the embodiment of the present disclosure may be located in a pixel area PXA provided in the display area DA. The pixel area PXA may include an emission area EMA and a non-emission area NEA.

The pixel circuit layer PCL and the display element layer DPL may be disposed on one surface of the substrate SUB to overlap with each other. In an example, the pixel area PXA of the substrate SUB may include the pixel circuit layer PCL disposed on the one surface of the substrate SUB and the display element layer DPL disposed on the pixel circuit layer PCL. However, the mutual positions of the pixel circuit layer PCL and the display element DPL on the substrate SUB may vary in some embodiments.

The substrate SUB may include a transparent insulating material to allow light to be transmitted therethrough. The substrate SUB may be a rigid substrate or a flexible substrate.

Circuit elements (e.g., a transistor T) constituting a pixel circuit PXC and predetermined signal lines electrically connected to the circuit elements may be disposed in each pixel area PXA of the pixel circuit layer PCL.

A light emitting element LD electrically connected to the pixel circuit PXC may be disposed in each pixel area PXA of the display element layer DPL.

The pixel circuit layer PCL may include a pixel circuit PXC including a transistor T and insulating layers disposed between components of the transistor T. For example, the insulating layers may include a buffer layer BFL, a gate insulating layer GI, an interlayer insulating layer ILD, and a via layer VIA which are sequentially stacked on the substrate SUB along the third direction DR3.

The via layer VIA may be entirely provided and/or formed on the first and second electrodes EL1 and EL2 of the transistor T and the interlayer insulating layer ILD. The via layer VIA may be an inorganic insulating layer including an inorganic material or an organic insulating layer including an organic material. The inorganic insulating layer may include, for example, at least one of silicon oxide (SiOₓ), silicon nitride (SiNₓ), silicon oxynitride (SiOₓN_{y}), and aluminum oxide (AlOₓ). The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin. In an embodiment, the via layer VIA may be an organic insulating layer including an organic material. The via layer VIA may be used as a planarization layer for reducing a step difference caused by components located thereunder.

In order to electrically connect the light emitting element LD and the transistor T to each other, the via layer VIA may be partially removed in an area corresponding to a portion of the transistor T.

The display element layer DPL may be located on the via layer VIA.

The display element layer DPL may include the light emitting element LD and a pixel defining layer PDL.

The light emitting element LD may include a pixel electrode AE, a light emitting layer EML, and a common electrode CE. Although not directly shown in the drawing, the light emitting element LD may be electrically connected to the transistor T.

The pixel electrode AE may be provided and/or formed on the via layer VIA. The pixel electrode AE may be an anode electrode of the light emitting element LD. The pixel electrode AE may be located in at least the emission area EMA.

The pixel electrode AE may be configured with a material having reflectivity. In an example, the pixel electrode AE may be made of a conductive material (or substance). The conductive material may include an opaque metal. The opaque metal may include, for example, metals such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and alloys thereof. However, the material of the pixel electrode AE is not limited to the above-described embodiment. In some embodiments, the pixel electrode AE may include a transparent conductive material (or substance). The transparent conductive material (or substance) may include a conductive oxide such as indium tin oxide (ITO), indium zinc oxide (IZO), zinc oxide (ZnO), indium gallium zinc oxide (IGZO), or indium tin zinc oxide (ITZO), a conductive polymer such as poly(3,4-ethylenedioxythiophene (PEDOT), and the like. When the pixel electrode AE includes a transparent conductive material (or substance), a separate conductive layer may be added which is formed of an opaque metal for reflecting light emitted from the light emitting layer EML in an image display direction of the display device DD (or an upper direction of the encapsulation layer TFE).

The pixel defining layer PDL may be located in the non-emission area NEA and define an emission area EMA of each pixel PXL. The pixel defining layer PDL may include an opening OP disposed in an area corresponding to one area of the pixel electrode AE. The opening OP of the pixel defining layer PDL may correspond to each emission area EMA.

The pixel defining layer PDL may be configured as an organic insulating layer including an organic material. The organic material may include acrylic resin, epoxy resin, phenolic resin, polyamide resin, polyimide resin, unsaturated polyester resin, poly-phenylene ether resin, poly-phenylene sulfide resin, benzocyclobutene resin, and the like. In some embodiments, the pixel defining layer PDL may include a light absorption material or have a light absorber coated thereon to absorb light introduced from the outside. For example, the pixel defining layer PDL may include a carbon-based black pigment. However, the present disclosure is not limited thereto.

The pixel defining layer PDL may protrude in the third direction DR3 from the via layer VIA along a circumference of the emission area EMA.

The light emitting layer EML may be disposed on the pixel electrode AE not covered by the pixel defining layer PDL.

The light emitting layer EML may be located on only the pixel electrode AE in the opening OP of the pixel defining layer PDL. The light emitting layer EML may be supplied to a desired area of a corresponding pixel PXL (e.g., the top of one area of the pixel electrode AE which is not covered by the pixel defining layer PDL) through an inkjet printing process, a process using a mask, or the like, but the process of forming the light emitting layer EML is not limited thereto. The light emitting layer EML may have a multi-layer thin film structure including a light generation layer for generating light. For example, the light emitting layer EML may include a hole injection layer for injecting holes, a hole transport layer for increasing a hole recombination opportunity by suppressing movement of electrons which are excellent in transportability of holes and are not combined in a light generation layer, the light generation layer for emitting light by recombination of the injected electrons and holes, a hole blocking layer for suppressing the movement of the holes that are not combined in the light generation layer, an electron transport layer for smoothly transporting the electrons to the light generation layer, and an electron injection layer for injecting the electrons. However, the present disclosure is not limited thereto.

The common electrode CE may be disposed over the light emitting layer EML.

The common electrode CE may be a cathode electrode of the light emitting element LD. The common electrode CE may be a common layer commonly provided to pixels PXL. The common electrode CE may be provided in a plate shape throughout the display area DA. The common electrode CE may be a thin metal layer having a thickness to a degree to which light emitted from the light emitting layer EML can be transmitted therethrough. The common electrode CE may be formed of a metal material to have a relatively thin thickness or be formed of a transparent conductive material. In an example, the common electrode CE may be configured with various transparent conductive materials. The common electrode CE may include at least one of various transparent conductive materials including indium tin oxide, indium zinc oxide, indium tin zinc oxide, aluminum zinc oxide, gallium zinc oxide, zinc tin oxide, and gallium tin oxide, and be formed substantially transparent or translucent to satisfy a predetermined transmittance. Accordingly, light emitted from the light emitting layer EML located on the bottom of the common electrode CE can be emitted upwardly through the common electrode CE and the encapsulating layer TFE.

The encapsulation layer TFE may be located on the common electrode CE.

The encapsulation layer TFE may be provided as a single layer, but be provided as a multi-layer. The encapsulation layer TFE may include a plurality of insulating layers covering the light emitting element LD. Specifically, the encapsulation layer TFE may include at least one inorganic layer and at least one organic layer. For example, the encapsulation layer TFE may have a structure in which an inorganic layer and an organic layer are alternately stacked. In some embodiments, the encapsulation layer TFE may be an encapsulation substrate which is disposed over the light emitting element LD and is joined with the substrate SUB through a sealant.

The encapsulation layer TFE may include first, second, and third encapsulation layers ENC1, ENC2, and ENC3 sequentially located on the common electrode CE. The first encapsulation layer ENC1 may be located on the display element layer DPL throughout the display area DA and at least a portion of the non-display area NDA. The second encapsulation layer ENC2 may be located on the first encapsulation layer ENC1 throughout the display area DA and at least a portion of the non-display area NDA. The third encapsulation layer ENC3 may be located on the second encapsulation layer ENC2 throughout the display area DA and at least a portion of the non-display area NDA. In some embodiments, the third encapsulation layer ENC3 may be located throughout the whole of the display area DA and the non-display area NDA.

In an embodiment, each of the first and third encapsulation layers ENC1 and ENC3 may be configured as an inorganic layer including an inorganic material and the second encapsulation layer ENC2 may be configured as an organic layer including an organic material. The inorganic layer may include, for example, silicon nitride (SiNₓ), silicon oxide (SiOₓ), silicon oxynitride (SiOₓN_{y}), or the like. The organic layer may include an organic insulating material such as acrylic resin, epoxy resin, phenolic resin, polyamides resin, polyimides resin, polyester resin, poly-phenylene sulfide resin, or benzocyclobutene (BCB).

In some embodiments, an optical layer including a color conversion layer and a color filter layer may be disposed on the encapsulation layer TFE.

In accordance with the present disclosure, there can be provided a transistor having improved reliability, a display device including the transistor and an electronic device including the display device.

A display device according to an embodiment is applicable to various types of electronic devices. In an embodiment, an electronic device includes the above-described display device and may further include other modules or devices having additional functions in addition to the display device.

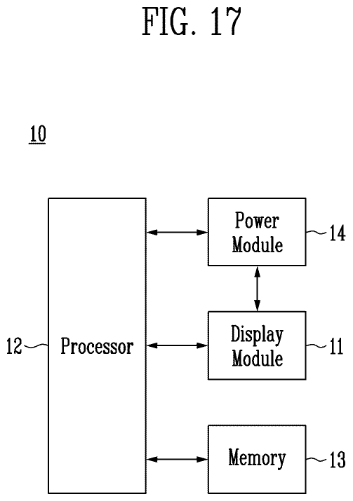

FIG. 17 is a block diagram of an electronic device according to an embodiment. Referring to FIG. 17, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module such as a power adapter or a battery device and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

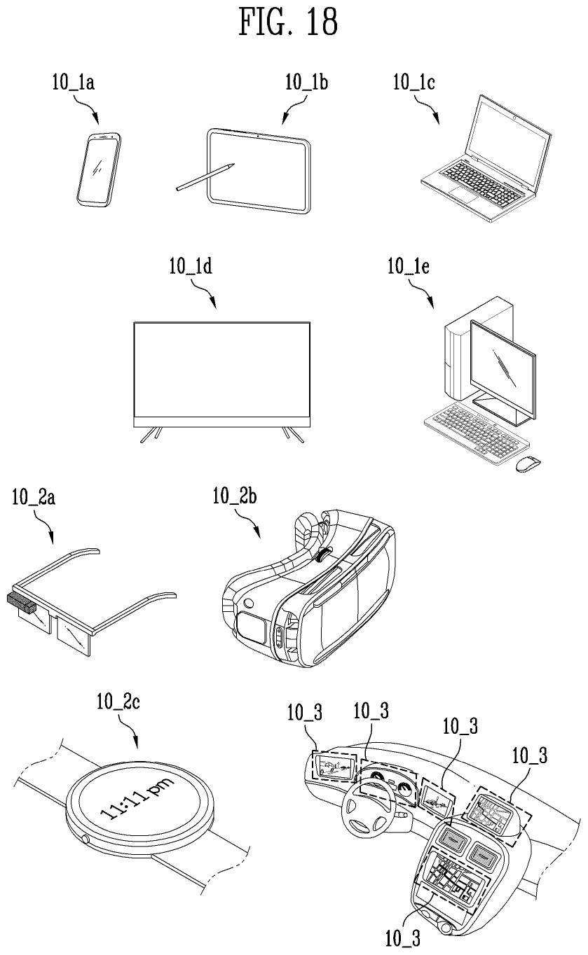

FIG. 18 shows schematic views of various embodiments of an electronic device.

Referring to FIG. 18, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display

In accordance with the present disclosure, there can be provided a manufacturing method of a transistor having improved reliability.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A display device comprising:
a buffer layer disposed on a substrate;
an oxide semiconductor layer disposed on the buffer layer and including a first region, a second region, and a channel region disposed between the first region and the second region;
a gate insulating layer disposed on the semiconductor layer;
a gate electrode disposed on the gate insulating layer, the gate electrode overlapping the channel region; and
an interlayer insulating layer disposed over the gate electrode,
wherein a concentration of hydrogen (H) in the buffer layer is 4×10²⁰ atoms/cm³ to 20×10²⁰ atoms/cm³.

2. The display device of claim 1, wherein, at a temperature of 400° C., a concentration of hydrogen gas (H₂) discharged from the buffer layer is 1×10¹⁹ atoms/cm³ to 10×10¹⁹ atoms/cm³, and
wherein, at a temperature of 400° C., a concentration of moisture (H₂O) discharged from the buffer layer is 1×10¹⁹ atoms/cm³ to 20×10¹⁹ atoms/cm³.

3. The display device of claim 1, wherein, at a temperature of 400° C., a concentration of hydrogen gas (H₂) discharged from the buffer layer is 1×10¹⁹ atoms/cm³ to 5×10¹⁹ atoms/cm³.

4. The display device of claim 1, wherein, at a temperature of 400° C., a concentration of moisture (H₂O) discharged from the buffer layer is 1×10¹⁹ atoms/cm³ to 10×10¹⁹ atoms/cm³.

5. The display device of claim 1, wherein a concentration of hydrogen (H) in the gate insulating layer is 5×10²⁰ atoms/cm³ to 30×10²⁰ atoms/cm³.

6. The display device of claim 5, wherein, at a temperature of 400° C., a concentration of hydrogen gas (H₂) discharged from the gate insulating layer is 10×10¹⁹ atoms/cm³ to 60×10¹⁹ atoms/cm³.

7. The display device of claim 1, wherein a concentration of hydrogen (H) in the interlayer insulating layer is 4×10²⁰ atoms/cm³ to 20×10²⁰ atoms/cm³.

8. The display device of claim 7, wherein, at a temperature of 400° C., a concentration of hydrogen gas (H₂) discharged from the interlayer insulating layer is 1×10¹⁹ atoms/cm³ to 10×10¹⁹ atoms/cm³.

9. The display device of claim 7, wherein, at a temperature of 400° C., a concentration of hydrogen gas (H₂) discharged from the interlayer insulating layer is 1×10¹⁹ atoms/cm³ to 7×10¹⁹ atoms/cm³.

10. The display device of claim 1, wherein a threshold voltage of the transistor is 0 V to −3.5 V.

11. The display device of claim 10, wherein a sheet resistance of the interlayer insulating layer is 1200 Ω/sq or less and
wherein the gate electrode includes aluminum.

12. A method of manufacturing a transistor, the method comprising:
forming a buffer layer;
forming a semiconductor layer on the buffer layer, the semiconductor layer including a first region, a second region, and a channel region disposed between the first region and the second region;
forming a gate insulating layer on the semiconductor layer;
forming a gate electrode on the gate insulating layer, the gate electrode overlapping the channel region; and
forming an interlayer insulating layer over the gate electrode,
wherein the buffer layer is formed such that a concentration of hydrogen (H) in the buffer layer is 4×10²⁰ atoms/cm³ to 20×10²⁰ atoms/cm³.

13. The method of claim 12, wherein the gate insulating layer is formed such that a concentration of hydrogen (H) in the gate insulating layer is 5×10²⁰ atoms/cm³ to 30×10²⁰ atoms/cm³, and
wherein the interlayer insulating layer is formed such that a concentration of hydrogen (H) in the interlayer insulating layer is 4×10²⁰ atoms/cm³ to 20×10²⁰ atoms/cm³.

14. The method of claim 12, wherein the buffer layer is formed such that, at a temperature of 400° C., a concentration of hydrogen gas (H₂) discharged from the buffer layer is 1×10¹⁹ atoms/cm³ to 10×10¹⁹ atoms/cm³, and a concentration of moisture (H₂O) discharged from the buffer layer is 1×10¹⁹ atoms/cm³ to 20×10¹⁹ atoms/cm³,
wherein the gate insulating layer is formed such that, at a temperature of 400° C., a concentration of hydrogen gas (H₂) discharged from the gate insulating layer is 10×10¹⁹ atoms/cm³ to 60×10¹⁹ atoms/cm³, and
wherein the interlayer insulating layer is formed such that, at a temperature of 400° C., a concentration of hydrogen gas (H₂) discharged from the interlayer insulating layer is 1×10¹⁹ atoms/cm³ to 10×10¹⁹ atoms/cm³.

15. The method of claim 14, wherein the forming of the semiconductor layer includes:
forming a base oxide semiconductor layer including an oxide semiconductor;
forming a buffer semiconductor layer by patterning the base oxide semiconductor layer; and
doping an impurity into both end portions of the buffer semiconductor layer.

16. An electronic device comprising:
a processor; and
a display device,
wherein the display device comprises:
a light emitting element; and
a transistor electrically connected to the light emitting element,
wherein the transistor includes:
a buffer layer disposed on a substrate;
an oxide semiconductor layer disposed on the buffer layer, the semiconductor layer including a first region, a second region, and a channel region disposed between the first region and the second region;
a gate insulating layer disposed on the semiconductor layer;
a gate electrode disposed on the gate insulating layer, the gate electrode overlapping the channel region; and
an interlayer insulating layer disposed over the gate electrode,
wherein a concentration of hydrogen (H) in the buffer layer is 4×10²⁰ atoms/cm³ to 20×10²⁰ atoms/cm³.

17. The electronic device of claim 16, wherein a concentration of hydrogen (H) in the gate insulating layer is 5×10²⁰ atoms/cm³ to 30×10²⁰ atoms/cm³,
wherein a concentration of hydrogen (H) in the interlayer insulating layer is 4×10²⁰ atoms/cm³ to 20×10²⁰ atoms/cm³,
wherein, at a temperature of 400° C., a concentration of hydrogen gas (H₂) discharged from the buffer layer is 1×10¹⁹ atoms/cm³ to 10×10¹⁹ atoms/cm³,
wherein, at a temperature of 400° C., a concentration of moisture (H₂O) discharged from the buffer layer is 1×10¹⁹ atoms/cm³ to 20×10¹⁹ atoms/cm³.

18. The electronic device of claim 17, wherein at a temperature of 400° C., a concentration of hydrogen gas (H₂) discharged from the gate insulating layer is 10×10¹⁹ atoms/cm³ to 60×10¹⁹ atoms/cm³, and
wherein, at a temperature of 400° C., a concentration of hydrogen gas (H₂) discharged from the interlayer insulating layer is 1×10¹⁹ atoms/cm³ to 10×10¹⁹ atoms/cm³.

19. The electronic device of claim 18, wherein a threshold voltage of the transistor is 0 V to −3.5 V.

20. The electronic device of claim 18, wherein a sheet resistance of the interlayer insulating layer is 1200 Ω/sq or less, and
wherein the gate electrode includes aluminum.
